(19) United States
(12) Patent Application Publication
(10) Pub. No.: US 2017/0272061 A1
(43) Pub. Date: Sep. 21, 2017

(54) VOLTAGE CLAMPING CIRCUIT

(71) Applicant: Industrial Technology Research Institute, Hsinchu (TW)

(72) Inventors: Yu-Lee Yeh, Hsinchu (TW); Chien-Nan Kuo, Hsinchu (TW)

(21) Appl. No.: 15/251,710

(22) Filed: Aug. 30, 2016

(30) Foreign Application Priority Data
Mar. 18, 2016 (TW) 105108435

(51) Int. Cl. H03K 5/08

(52) U.S. Cl. CPC H03K 5/08

(57) ABSTRACT

A voltage clamping circuit is provided. In an embodiment, the voltage clamping circuit includes a plurality of gain shifting circuits and a signal processing circuit. The plurality of gain shifting circuits receive an input voltage and voltage levels to generate a plurality of shifted voltages. The signal processing circuit generates a difference value of the plurality of shifted voltages to generate an output voltage according to the difference value, such that the voltage clamping circuit achieves an implementation of a passing band or a rejection of the input voltage.

### CROSS-REFERENCE TO RELATED APPLICATION

This application claims the priority benefit of Taiwan application serial no. 105108435, filed on Mar. 18, 2016. The entirety of the Taiwan application is hereby incorporated by reference herein.

### TECHNICAL FIELD

The disclosure relates to a voltage clamping circuit.

### BACKGROUND

In some circuits (for example, an analog front end circuit in a high speed oscilloscope), overlarge amplitudes (whether positive or negative) of input signals should be limited to avoid overvoltage in the circuits. In some circuits, overvoltage may influence characteristics of the circuits. In addition, input signals for these circuits should be input without distortion in a specific range, so that the oscilloscope may process and display the input signals properly.

Therefore, diode components are used to clamp voltages in some circuits to satisfy the aforementioned requirement. However, high-speed diode components are not provided in some semiconductor processes. Besides, control and adjustment of the central voltage level is difficult in some voltage clamping circuits with diode components, which results in high design complexity and high cost.

Consequently, the aforementioned issues become the problems to be solved in the art.

### SUMMARY

The disclosure provides a voltage clamping circuit, which may achieve function of high speed voltage clamping with an integrated circuit process which does not provide high speed diode components. The design complexity and adjustment of the clamping voltage level is simple. Therefore, the voltage clamping circuit may be implemented in an integrated circuit and/or a system circuit.

The disclosure provides a voltage clamping circuit. In an embodiment, the voltage clamping circuit includes a first gain shifting circuit, a second gain shifting circuit, and a signal processing circuit. The first gain shifting circuit receives an input voltage and a first voltage level to perform a first gain shifting of the input voltage to generate a first shifted voltage. The second gain shifting circuit receives the input voltage and a second voltage level to perform a second gain shifting of the input voltage to generate a second shifted voltage. The signal processing circuit receives the first shifted voltage and the second shifted voltage to generate a difference value of the first shifted voltage and the second shifted voltage, and generates an output voltage according to the difference value, so that the voltage clamping circuit achieves an implementation of a passing band or a rejection band of the input voltage.

The disclosure further provides a voltage clamping circuit. In another embodiment, the voltage clamping circuit includes a first gain shifting circuit, a second gain shifting circuit, a third gain shifting circuit, a fourth gain shifting circuit, and a signal processing circuit. The first gain shifting circuit receives a first input voltage and a first voltage level to perform a first gain shifting of the first input voltage to generate a first shifted voltage. The second gain shifting circuit receives the first input voltage and a second voltage level to perform a second gain shifting of the first input voltage to generate a second shifted voltage. The third gain shifting circuit receives a second input voltage and the first voltage level to perform a third gain shifting of the second input voltage to generate a third shifted voltage. The fourth gain shifting circuit receives the second input voltage and the second voltage level to perform a fourth gain shifting of the second input voltage to generate a fourth shifted voltage. The signal processing circuit receives the first shifted voltage, the second shifted voltage, the third shifted voltage, and the fourth shifted voltage to generate an output voltage, so that the voltage clamping circuit achieves an implementation of a passing band or a rejection band of the first input voltage and the second input voltage.

In the disclosure, the voltage clamping circuit uses a plurality of gain shifting circuits and a signal processing circuit to generate an output voltage, so that the voltage clamping circuit achieves the implementation of a passing band or a rejection band of an input voltage. Therefore, the high speed voltage clamping may be achieved by a circuit without a diode component, and the adjustment of the central voltage level is simple.

### BRIEF DESCRIPTION OF THE DRAWINGS

FIG. 1A is a block diagram of a voltage clamping circuit in accordance with an embodiment of the disclosure.

FIG. 1B is a diagram showing gain shift responses of the shifted voltages and difference values of the gain shift responses of the shifted voltages in accordance with an embodiment of the disclosure.

FIG. 2 is an exemplary circuit diagram of the voltage clamping circuit in accordance with an embodiment of the disclosure.

FIG. 3 is an exemplary circuit diagram of the voltage clamping circuit in accordance with another embodiment of the disclosure.

FIG. 4 is a simulation result diagram of signals shown in FIG. 2 under various conditions.

FIG. 5 is a block diagram of a voltage clamping circuit in accordance with another embodiment of the disclosure.

FIG. 6 is an exemplary circuit diagram of the voltage clamping circuit in accordance with another embodiment of the disclosure.

FIG. 7 is an exemplary circuit diagram of the voltage clamping circuit in accordance with another embodiment of the disclosure.

### DETAILED DESCRIPTION OF DISCLOSED EMBODIMENTS

Below, exemplary embodiments will be described in detail with reference to accompanying drawings so as to be easily realized by a person having ordinary knowledge in the art. The inventive concept may be embodied in various forms without being limited to exemplary embodiments set forth herein. Descriptions of well-known parts are omitted for clarity, and like reference numerals refer to like elements throughout.

The term “couple” or “coupled” used in the disclosure and the claims may refer to any direct or indirect connection. For example, when describing a first device coupled to a second device, the first device may be connected to the second device directly, or the first device may be connected to the second device indirectly through any other devices, methods, or connection techniques. In addition, sequence of terms (for example, first, second, third, fourth, etc.) used to describe components in embodiments or claims are used as references of the components, and do not necessarily represent formation sequences, arranging sequences, or position sequences of the components.

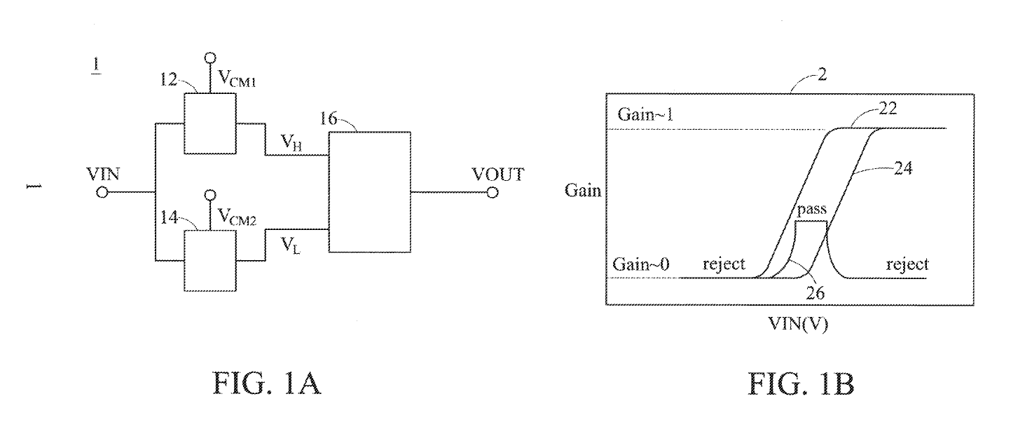

FIG. 1A is a block diagram of a voltage clamping circuit 1 in accordance with an embodiment of the disclosure. The voltage clamping circuit 1 includes a first gain shifting circuit 12, a second gain shifting circuit 14, and a signal processing circuit 16.

The first gain shifting circuit 12 receives an input voltage VIN and a first voltage level V_{CM1} to perform a first gain shifting of the input voltage VIN to generate a first shifted voltage V_{H}.

The second gain shifting circuit 14 receives the input voltage VIN and a second voltage level V_{CM2} to perform a second gain shifting of the input voltage VIN to generate a second shifted voltage V_{L}.

The signal processing circuit 16 receives the first shifted voltage V_{H} and the second shifted voltage V_{L} to generate a difference value of the first shifted voltage V_{H} and the second shifted voltage V_{L}. The difference value F, for example, is generated by F=V_{H}−V_{L} or F=V_{L}−V_{H}. The signal processing circuit 16 generates an output voltage VOUT according to the difference value, so that the voltage clamping circuit 1 achieves an implementation of a passing band or a rejection band of the input voltage VIN. The output voltage VOUT, for example, is generated by VOUT=F=V_{H}−V_{L} or VOUT=F=V_{L}−V_{H}. In this embodiment, a common mode rejection is used for generating the difference value of the first shifted voltage V_{H} and the second shifted voltage V_{L}. However, the disclosure is not limited thereto.

FIG. 1B is a diagram showing gain shift responses of the shifted voltages and the difference value of the gain shift responses of the shifted voltages in accordance with an embodiment of the disclosure. In FIG. 1B, curve 22 in the gain diagram 2 is a first shifted gain, which is a gain response of the first shifted voltage V_{H}. Curve 24 is a second shifted gain, which is a gain response of the second shifted voltage V_{L}. Curve 26 is a difference value of the first shifted gain and the second shifted gain. The difference value of the first shifted gain and the second shifted gain, for example, is generated by the gain response of V_{H}−V_{L} or V_{L}−V_{H}, that is Gain(V_{H}−V_{L}) or Gain(V_{L}−V_{H}). As shown in FIG. 1B, a middle part of the curve 26 is a passing band, and two sides of the curve 26 are rejection bands. “Gain˜1” means that gain approximates 1, and “Gain˜0” means that gain approximates 0.

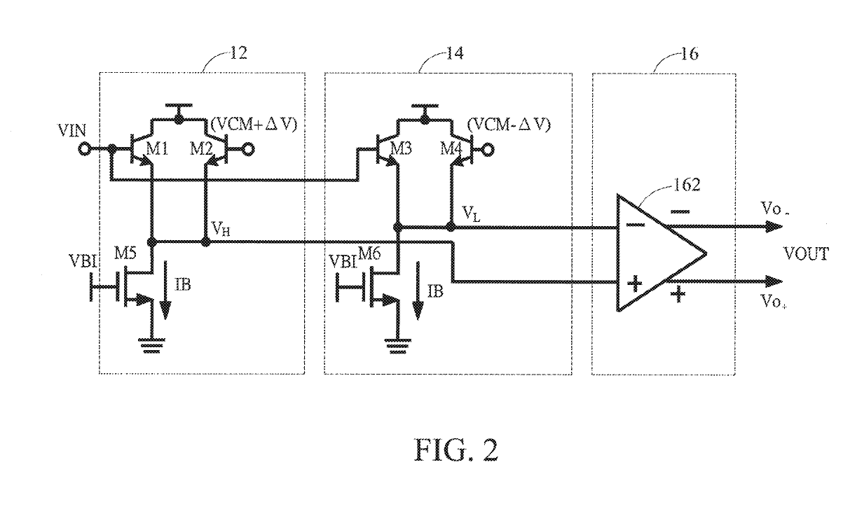

FIG. 2 is an exemplary circuit diagram of the voltage clamping circuit in accordance with an embodiment of the disclosure.

As shown in FIG. 2, the first gain shifting circuit 12 includes a first transistor M1 and a second transistor M2. The first transistor M1 includes a first terminal, a second terminal, and a third terminal. The first terminal of the first transistor M1 receives the input voltage VIN. The second transistor M2 includes a first terminal, a second terminal, and a third terminal. The first terminal of the second transistor M2 receives the first voltage level (VCM+ΔV) which may be the V_{CM1} of FIG. 1A. The second terminal of the second transistor M2 is coupled to the second terminal of the first transistor M1 to generate the first shifted voltage V_{H}. The third terminal of the first transistor M1 is coupled to the third terminal of the second transistor M2. The third terminal of the first transistor M1 and the third terminal of the second transistor M2 are coupled to a power source.

The second gain shifting circuit 14 includes a third transistor M3 and a fourth transistor M4. The third transistor M3 includes a first terminal, a second terminal, and a third terminal. The first terminal of the third transistor M3 receives the input voltage VIN. The fourth transistor M4 includes a first terminal, a second terminal, and a third terminal. The first terminal of the fourth transistor M4 receives the second voltage level (VCM−ΔV) which may be the V_{CM2} of FIG. 1A. The second terminal of the fourth transistor M4 is coupled to the second terminal of the third transistor M3 to generate the second shifted voltage V_{L}. The third terminal of the third transistor M3 is coupled to the third terminal of the fourth transistor M4. The third terminal of the third transistor M3 and the third terminal of the fourth transistor M4 are coupled to the power source. The first voltage level (VCM+ΔV) is different from the second voltage level (VCM−ΔV).

The signal processing circuit 16 includes an operational amplifier (op-amp) 162. The operational amplifier 162 includes a first input terminal (+) and a second input terminal (−). The first input terminal (+) of the operational amplifier 162 receives the first shifted voltage V_{H}. The second input terminal (−) of the operational amplifier 162 receives the second shifted voltage V_{L}. The operational amplifier 162 generates a difference value of the first shifted voltage V_{H} and the second shifted voltage V_{L}, so as to generate the output voltage VOUT according to the difference value of the first shifted voltage V_{H} and the second shifted voltage V_{L}. In one embodiment, the output voltage VOUT may be generated by subtracting a second output terminal Vo₋ of the operational amplifier 162 from a first output terminal Vo₊of the operational amplifier 162, or the output voltage VOUT may be generated by subtracting the first output terminal Vo, of the operational amplifier 162 from the second output terminal Vo₋ of the operational amplifier 162. In this embodiment, common mode rejection is used for generating the difference value of the first shifted voltage V_{H} and the second shifted voltage V_{L}. However, the disclosure is not limited thereto. In this embodiment, the operational amplifier 162 is used as an example of the signal processing circuit 16. However, the disclosure is not limited thereto. In another embodiment, other circuits may be used as the signal processing circuit 16 to achieve aforementioned implementation of signal/energy subtraction.

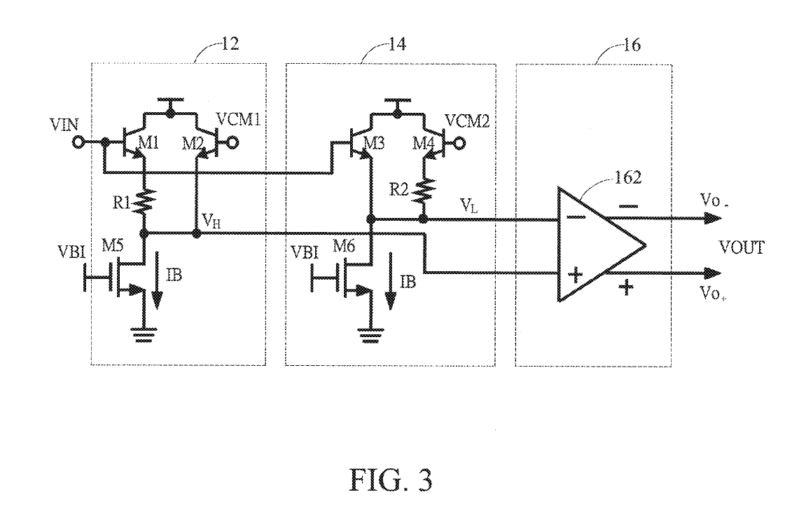

FIG. 3 is an exemplary circuit diagram of the voltage clamping circuit in accordance with another embodiment of the disclosure.

As shown in FIG. 3, the first gain shifting circuit 12 includes a first transistor M1 and a second transistor M2. The first transistor M1 includes a first terminal, a second terminal, and a third terminal. The first terminal of first transistor M1 receives the input voltage VIN. The second terminal of first transistor M1 is coupled to one terminal of a first resistor R1. The second transistor M2 includes a first terminal, a second terminal, and a third terminal. The first terminal of the second transistor M2 receives a first voltage level VCM1, and the second terminal of the second transistor M2 is coupled to the other terminal of the first resistor R1 to generate the first shifted voltage V_{H}. The third terminal of the first transistor M1 is coupled to the third terminal of the second transistor M2. The third terminal of the first transistor M1 and the third terminal of the second transistor M2 are coupled to a power source. In this embodiment, the first resistor R1 may be used for generating a voltage drop ΔV₁. More specifically, ΔV₁ may be generated by ΔV₁=R1*IB, wherein IB is a constant current.

The second gain shifting circuit 14 includes a third transistor M3 and a fourth transistor M4. The third transistor M3 includes a first terminal, a second terminal, and a third terminal. The first terminal of the third transistor M3 receives the input voltage VIN. The fourth transistor M4 includes a first terminal, a second terminal, and a third terminal. The first terminal of the fourth transistor M4 receives the second voltage level VCM2. The second terminal of the fourth transistor M4 is coupled to one terminal of a second resistor R2, and the other terminal of the second resistor R2 is coupled to the second terminal of the third transistor M3 to generate the second shifted voltage V_{L}. The third terminal of the third transistor M3 is coupled to the third terminal of the fourth transistor M4. The third terminal of the third transistor M3 and the third terminal of the fourth transistor M4 are coupled to the power source. In an embodiment, a value of the first resistor R1 and a value of the second resistor R2 are the same. In an embodiment, the first voltage level VCM1 and the second voltage level VCM2 are the same. In this embodiment, the second resistor R2 may be used for generating a voltage drop ΔV₂. More specifically, ΔV₂ may be generated by ΔV₂=R2*IB. In this embodiment, the voltage drop ΔV₁ and the voltage drop ΔV₂ are the same. It is noted that “the same” may mean “exactly the same” or “substantially the same” in the disclosure.

The signal processing circuit 16 includes an operational amplifier 162. The operational amplifier 162 include a first input terminal (+) and a second input terminal (−). The first input terminal (+) of the operational amplifier 162 receives the first shifted voltage V_{H}. The second input terminal (−) of the operational amplifier 162 receives the second shifted voltage V_{L}. The operational amplifier 162 generates a difference value of the first shifted voltage V_{H} and the second shifted voltage V_{L}, so as to generate the output voltage VOUT according to the difference value of the first shifted voltage V_{H} and the second shifted voltage V_{L}. In one embodiment, the output voltage VOUT may be generated by subtracting a second output terminal (Vo₋) of the operational amplifier 162 from a first output terminal (Vo₊) of the operational amplifier 162, or the output voltage VOUT may be generated by subtracting the first output terminal (Vo₊) of the operational amplifier 162 from the second output terminal (Vo₋) of the operational amplifier 162.

Other circuits in FIGS. 2 and 3, for example, the first gain shifting circuit 12 shown in FIG. 2, may further include a transistor M5. A first terminal of transistor M5 receives a bias voltage VBI. A third terminal of the transistor M5 is coupled to the second terminal of the first transistor M1 and the second terminal of the second transistor M2 to provide a constant current IB. A second terminal of the transistor M5 is coupled or connected to ground. A transistor M6 is similar to the transistor M5. In this embodiment, the transistor M5 and the transistor M6 provide constant currents IBs as current sources. However, the disclosure is not limited thereto. In another embodiment, one or more current sources may be used to implement the function of the transistor M5 and/or the transistor M6 to provide constant currents IBs. In this embodiment, the transistor M5 and/or the transistor M6 may be a metal-oxide-semiconductor field-effect transistor (MOSFET). However, the disclosure is not limited thereto.

In the above embodiments, the voltage clamping circuit operates at a high frequency in a range of such as 1 GHz to 3 GHz, 3 GHz to 5 GHz, or 1 GHz to 5 GHz. High speed diode components operating at a high frequency are not provided in some semiconductor processes. According to some embodiments of the disclosure, high speed voltage clamping at the high frequency may be achieved without diode components. In addition, according to some embodiments of the disclosure, the voltage clamping circuit may be applied to some semiconductor processes which do not provide high speed P-type components, such as P-type metal-oxide-semiconductor field effect transistors (PMOS) or PNP Bipolar Junction Transistor (PNP BJT).

Moreover, since input terminals of some voltage clamping circuits are low impedances (low Z), a large capacitor or a linear low-dropout regulator (LDO) is generally used in these voltage clamping circuits, which results in high design complexity for implementing circuits operating at a low frequency. Besides, since the design of the voltage level should consider a characteristic voltage of the diode component, the operation range may be limited, and the clamping voltage level is not easy to be designed precisely. However, in the aforementioned embodiments, since the input terminal of the voltage clamping circuit is designed to be high impedance (High Z), the design of the voltage level may be implemented by a resistor voltage divider. Therefore, according to some embodiments in the disclosure, the voltage clamping circuit may be operated at the high frequency and the low frequency.

In addition, the design complexity and the costs of some voltage clamping circuits are high. However, according to some embodiments of the disclosure, the design for the voltage clamping function in the voltage clamping circuit is independent. Therefore, the design complexity and the influence of the parasitic characteristics of additional components are lowered. Besides, the voltage clamping may be adjusted by linear components according to some embodiments of the disclosure. Therefore, according to some embodiments of the disclosure, the design complexity of the voltage clamping circuit is low and the cost is low.

It is noted that although bipolar junction transistors (BJTs) are used as examples of the transistors M1-M4 in FIGS. 2 and 3, the disclosure is not limited thereto. In one embodiment, the transistors M1-M4 may be MOSFETs. In another embodiment, the transistors M1-M4 may be any combination of BJTs and MOSFETs. Taken a BJT shown in FIGS. 2 and 3 as an example, a first terminal of the BJT is a base terminal, a second terminal of the BJT is an emitter terminal, and a third terminal of the BJT is a collector terminal. If a MOSFET is used for any transistor of transistors M1-M4 in FIGS. 2 and 3, for example, a first terminal of the MOSFET is a gate terminal, a second terminal of the MOSFET is a source terminal, and a third terminal of the MOSFET is a drain terminal. However, the disclosure is not limited thereto. In addition, the transistors in embodiments of the disclosure may be N-type transistors or P-type transistors.

According to aforementioned embodiments, the voltage clamping circuit in some embodiments of the disclosure may be implemented without diode components and/or voltage detecting feedback circuit. According to some embodiments of the disclosure, the voltage clamping circuit uses two signal transferring circuits and one signal processing circuit to implement the function of high speed voltage clamping with the manufacturing process of an integrated circuit but without high speed diode components therein. In addition, according to some embodiments of the disclosure, the output signal is processed and outputted directly, which is faster than the speed of feedback control. The design complexity and adjustment of the clamping voltage level is simple. Therefore, the voltage clamping circuit may be implemented in an integrated circuit and/or a system circuit.

Referring to FIG. 2 again, it is assumed that G1 is a gain of the first gain shifting circuit 12 and G2 is a gain of the second gain shifting circuit 14.

In a first condition, if a value of VIN is greater than a value of VCM, and a difference between the value of VIN and the value of VCM is much greater (for example, 10 times greater) than a value of ΔV (in other words, if a value of (VIN−VCM) is much greater than the value of ΔV), the transistor M2 and the transistor M4 are off. Therefore, G1=G2=1 (in other words, G1−G2=0) and VOUT=Vo₊−Vo₋. In this embodiment, Vo₊is VIN*G1 and Vo₋ is VIN*G2. Therefore, VOUT=VIN*|(G1−G2)|=0. In this disclosure, |(G1−G2)| denotes an absolute value of (G1−G2).

In a second condition, if the value of VIN is between a value of (VCM−ΔV) and a value of (VCM+ΔV), G1≠G2. In other words, G1−G2=K, wherein a new gain K may be a constant, or K may be not equal to 0. In this condition, VOUT=VIN*|(G1−G2)|=VIN*K.

In a third condition, if the value of VIN is less than the value of VCM, and a difference between the value of VIN and the value of VCM is much greater (for example, 10 times greater) than the value of ΔV (in other words, if a value of (VCM−VIN) is much greater than the value of ΔV), the transistor M1 and the transistor M3 are off. Therefore, G1=G2=0 (in other words, G1−G2=0) and VOUT=Vo₊−Vo₋. In this embodiment, Vo₊ is VIN*G1 and Vo₋ is VIN*G2. Therefore, VOUT=VIN*|(G1−G2)|=0.

It is noted that the above description is described by mathematical operations for easy to understand. However, the signal processing circuit 16 is not limited to a mathematical operation circuit or a digital circuit. In one embodiment, the signal processing circuit 16 is an analog circuit and the operation of subtraction may be implemented by an energy subtraction of signals. In addition, since there may be an error (or inaccuracy) in a circuit, the equal sign “=” does not necessarily mean equal, the equal sign “=” may mean exactly equal or substantially equal. For example, in the equation of G1−G2=0, G1−G2 is not necessarily equal to 0. The equation of G1−G2=0 may mean that G1−G2 is substantially equal to 0.

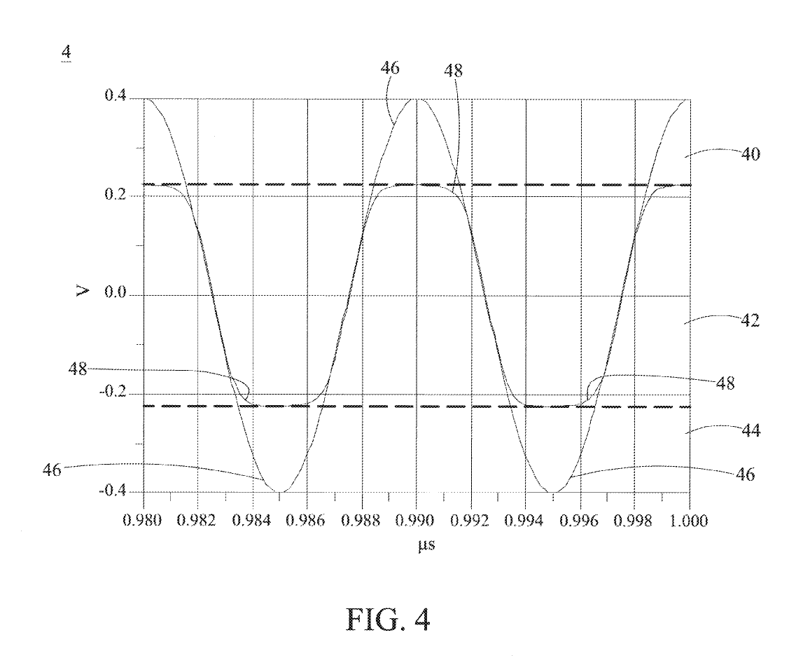

FIG. 4 is a simulation result diagram 4 of signals shown in FIG. 2 under various conditions, wherein the new gain K is adjusted to 1.

In FIG. 4, a first region 40, a second region 42, and a third region 44 depict the first condition, the second condition, and the third condition mentioned above, respectively. A curve 46 represents the input voltage VIN and a curve 48 represents the output voltage VOUT.

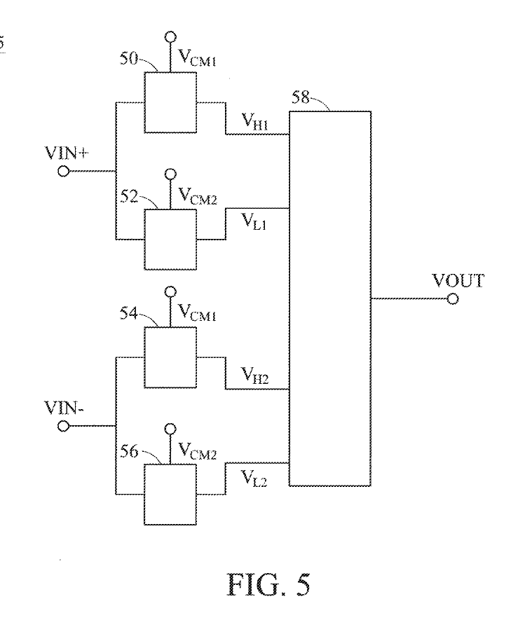

FIG. 5 is a block diagram of a voltage clamping circuit in accordance with another embodiment of the disclosure. A voltage clamping circuit 5 includes a first gain shifting circuit 50, a second gain shifting circuit 52, a third gain shifting circuit 54, a fourth gain shifting circuit 56, and a signal processing circuit 58. The voltage clamping circuit 5 uses a differential circuit to enhance the function of voltage clamping and to achieve better linearity of a passing band of input voltages.

The first gain shifting circuit 50 receives a first input voltage VIN+ and a first voltage level V_{CM1} to perform a gain shifting of the first input voltage VIN+ to generate a first shifted voltage V_{H1}.

The second gain shifting circuit 52 receives the first input voltage VIN+ and a second voltage level V_{CM2} to perform a gain shifting of the first input voltage VIN+ to generate a second shifted voltage V_{L1}.

The third gain shifting circuit 54 receives a second input voltage VIN− and the first voltage level V_{CM1} to perform a gain shifting of the second input voltage VIN− to generate a third shifted voltage V_{H2}.

The fourth gain shifting circuit 56 receives the second input voltage VIN− and the second voltage level V_{CM2} to perform a gain shifting of the second input voltage VIN− to generate a fourth shifted voltage V_{L2}.

The signal processing circuit 58 receives the first shifted voltage V_{H1}, the second shifted voltage V_{L1}, the third shifted voltage V_{H2}, and the fourth shifted voltage V_{L2} to generate an output voltage VOUT, so that the voltage clamping circuit 5 achieves the implementation of a passing band or a rejection band of the first input voltage VIN+ and the second input voltage VIN−.

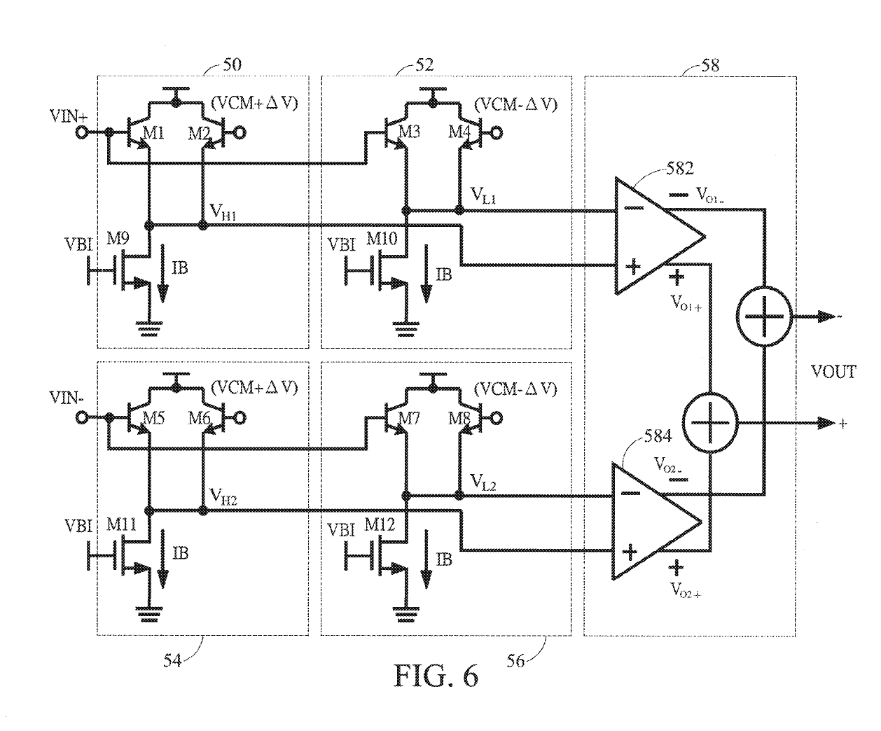

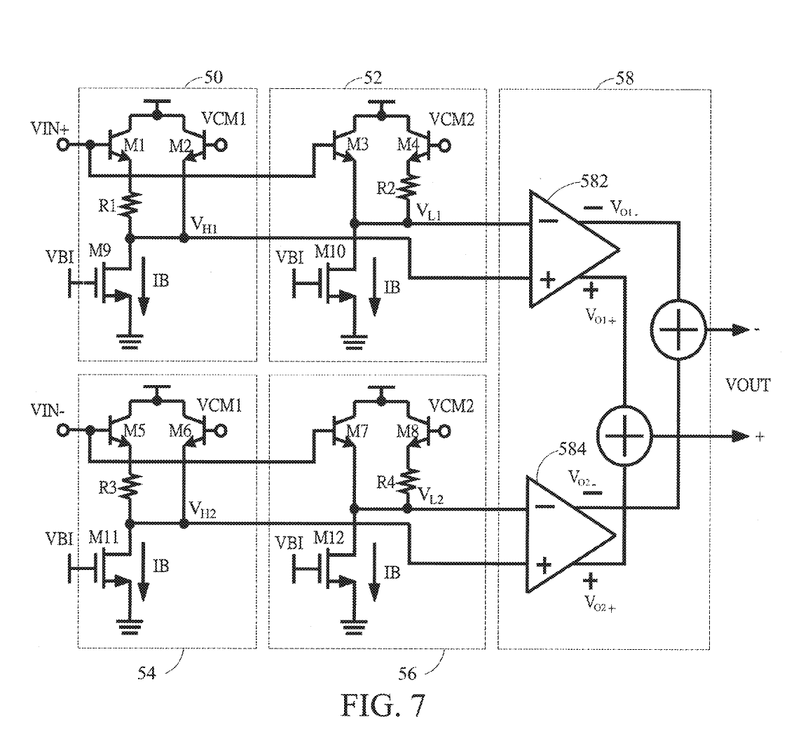

In this embodiment, the third gain shifting circuit 54 and the fourth gain shifting circuit 56 are added to implement the differential circuit. The first gain shifting circuit 50 and the second gain shifting circuit 52 generate one pair of a positive terminal and a negative terminal (for example, the first shifted voltage V_{H1} and the second shifted voltage V_{L1}). The third gain shifting circuit 54 and the fourth gain shifting circuit 56 generate another pair of a positive terminal and a negative terminal (for example, the third shifted voltage V_{H2} and the fourth shifted voltage V_{L2}). The energies of the positive terminals in both pairs (for example, the first shifted voltage V_{H1} and the third shifted voltage V_{H2}) are combined and the energies of the negative terminals in both pairs (for example, the second shifted voltage V_{L1} and the fourth shifted voltage V_{L2}) are combined to generate output voltage VOUT. Therefore, the distortion may be lower. Embodiments shown in FIGS. 6 and 7 are described in detail.

FIG. 6 is an exemplary circuit diagram of the voltage clamping circuit in accordance with another embodiment of the disclosure.

The first gain shifting circuit 50 includes a first transistor M1 and a second transistor M2. The first transistor M1 includes a first terminal, a second terminal, and a third terminal. The first terminal of the first transistor M1 receives a first input voltage VIN+. The second transistor M2 includes a first terminal, a second terminal, and a third terminal. The first terminal of the second transistor M2 receives the first voltage level (VCM+ΔV) which may be the V_{CM1} of FIG. 5. The second terminal of the second transistor M2 is coupled to the second terminal of the first transistor M1 to generate the first shifted voltage V_{H1}. The third terminal of the first transistor M1 is coupled to the third terminal of the second transistor M2. The third terminal of the first transistor M1 and the third terminal of the second transistor M2 are coupled to a power source.

The second gain shifting circuit 52 includes a third transistor M3 and a fourth transistor M4. The third transistor M3 includes a first terminal, a second terminal, and a third terminal. The first terminal of the third transistor M3 receives the first input voltage VIN+. The fourth transistor M4 includes a first terminal, a second terminal, and a third terminal. The first terminal of the fourth transistor M4 receives the second voltage level (VCM−ΔV) which may be the V_{CM2} of FIG. 5. The second terminal of the fourth transistor M4 is coupled to the second terminal of the third transistor M3 to generate the second shifted voltage V_{L1}. The third terminal of the third transistor M3 is coupled to the third terminal of the fourth transistor M4. The third terminal of the third transistor M3 and the third terminal of the fourth transistor M4 are coupled to the power source.

The third gain shifting circuit 54 includes a fifth transistor M5 and a sixth transistor M6. The fifth transistor M5 includes a first terminal, a second terminal, and a third terminal. The first terminal of the fifth transistor M5 receives the second input voltage VIN−. The sixth transistor M6 includes a first terminal, a second terminal, and a third terminal. The first terminal of the sixth transistor M6 receives the first voltage level (VCM+ΔV) which may be the V_{CM1} of FIG. 5. The second terminal of the sixth transistor M6 is coupled to the second terminal of the fifth transistor M5 to generate the third shifted voltage V_{H2}. The third terminal of the fifth transistor M5 is coupled to the third terminal of the sixth transistor M6. The third terminal of the fifth transistor M5 and the third terminal of the sixth transistor M6 are coupled to the power source.

The fourth gain shifting circuit 56 includes a seventh transistor M7 and an eighth transistor M8. The seventh transistor M7 includes a first terminal, a second terminal, and a third terminal. The first terminal of the seventh transistor M7 receives the second input voltage VIN−. The eighth transistor M8 includes a first terminal, a second terminal, and a third terminal. The first terminal of the eighth transistor M8 receives the second voltage level (VCM−ΔV) which may be the V_{CM2} of FIG. 5. The second terminal of the eighth transistor M8 is coupled to the second terminal of the seventh transistor M7 to generate the second shifted voltage V_{L2}. The third terminal of the seventh transistor M7 is coupled to the third terminal of the eighth transistor M8. The third terminal of the seventh transistor M7 and the third terminal of the eighth transistor M8 are coupled to the power source. The first voltage level (VCM+ΔV) is different from the second voltage level (VCM−ΔV).

The signal processing circuit 58 includes a first operational amplifier 582 and a second operational amplifier 584. The first operational amplifier 582 includes a first input terminal (+) and a second input terminal (−). The first input terminal (+) of the first operational amplifier 582 receives the first shifted voltage V_{H1}. The second input terminal (−) of the first operational amplifier 582 receives the second shifted voltage V_{L1}. The second operational amplifier 584 includes a first input terminal (+) and a second input terminal (−). The first input terminal (+) of the second operational amplifier 584 receives the third shifted voltage V_{H2}. The second input terminal (−) of the second operational amplifier 584 receives the fourth shifted voltage V_{L2}. The first operational amplifier 582 generates a first positive output (for example, Vₒ₁₊) and a first negative output (for example, Vₒ₁₋) according to the first shifted voltage V_{H1} and the second shifted voltage V_{L1}. The second operational amplifier 584 generates a second positive output (for example, Vₒ₂₊) and a second negative output (for example, Vₒ₂₋) according to the third shifted voltage V_{H2} and the fourth shifted voltage V_{L2}. Thereafter, an energy of a signal of the first positive output and an energy of a signal of the second positive output are combined, and an energy of a signal of the first negative output and an energy of a signal of the second negative output are combined, so as to generate a differential output signal VOUT. In this embodiment, the differential output signal VOUT includes a first differential output terminal (+) and a second differential output terminal (−). In this embodiment, the first differential output terminal (+) of the differential output signal VOUT is a positive terminal with a voltage value of (Vₒ₁₊+Vₒ₂₊). The second differential output terminal (−) of the differential output signal VOUT is a negative terminal with a voltage value of (Vₒ₁₋+Vₒ₂₋).

In this embodiment of FIG. 6, similar to conditions in description related to FIG. 2, it is assumed that G1 is a gain of the first gain shifting circuit 50, G2 is a gain of the second gain shifting circuit 52, G3 is a gain of the third gain shifting circuit 54, and G4 is a gain of the fourth gain shifting circuit 56. In a first condition, a value of VIN+ (or VIN−) is greater than a value of VCM, and a difference between the value of VIN+ (or VIN−) and the value VCM is much greater than a value of ΔV. In a third condition, the value of VIN+ (or VIN−) is less than the value of VCM, and a difference between the value of VIN+ (or VIN−) and the value of VCM is much greater than the value of ΔV. In the first condition or in the third condition, G1=G2 and G3=G4. Therefore, G1−G2=0 and G3−G4=0. Consequently, VOUT=0. It is noted that the above description is described by mathematical operations for easy to understand. However, the signal processing circuit 58 is not limited to a mathematical operation circuit or a digital circuit. In one embodiment, the signal processing circuit 58 is an analog circuit and the operation of addition may be implemented by an energy combination of signals. In addition, since there may be an error (or inaccuracy) in a circuit, the equal sign “=” does not necessarily mean equal, the equal sign “=” may mean exactly equal or substantially equal. For example, in the equation of G1−G2=0, G1−G2 is not necessarily equal to 0. The equation of G1−G2=0 may mean that G1−G2 is substantially equal to 0.

FIG. 7 is an exemplary circuit diagram of the voltage clamping circuit in accordance with another embodiment of the disclosure.

The first gain shifting circuit 50 includes a first transistor M1 and a second transistor M2. The first transistor M1 includes a first terminal, a second terminal, and a third terminal. The first terminal of first transistor M1 receives the first input voltage VIN+. The second terminal of first transistor M1 is coupled to one terminal of a first resistor R1. The second transistor M2 includes a first terminal, a second terminal, and a third terminal. The first terminal of the second transistor M2 receives the first voltage level VCM1, and the second terminal of the second transistor M2 is coupled to the other terminal of the first resistor R1 to generate the first shifted voltage V_{H1}. The third terminal of first transistor M1 is coupled to the third terminal of the second transistor M2. The third terminal of first transistor M1 and the third terminal of the second transistor M2 are coupled to a power source.

The second gain shifting circuit 52 includes a third transistor M3 and a fourth transistor M4. The third transistor M3 includes a first terminal, a second terminal, and a third terminal. The first terminal of the third transistor M3 receives the first input voltage VIN+. The fourth transistor M4 includes a first terminal, a second terminal, and a third terminal. The first terminal of the fourth transistor M4 receives the second voltage level VCM2. The second terminal of the fourth transistor M4 is coupled to one terminal of a second resistor R2, and the other terminal of the second resistor R2 is coupled to the second terminal of the third transistor M3 to generate the second shifted voltage V_{L1}. The third terminal of the third transistor M3 is coupled to the third terminal of the fourth transistor M4. The third terminal of the third transistor M3 and the third terminal of the fourth transistor M4 are coupled to the power source.

The third gain shifting circuit 54 includes a fifth transistor M5 and a sixth transistor M6. The fifth transistor M5 includes a first terminal, a second terminal, and a third terminal. The first terminal of fifth transistor M5 receives the second input voltage VIN−. The second terminal of fifth transistor M5 is coupled to one terminal of a third resistor R3. The sixth transistor M6 includes a first terminal, a second terminal, and a third terminal. The first terminal of the sixth transistor M6 receives the first voltage level VCM1, and the second terminal of the sixth transistor M6 is coupled to the other terminal of the third resistor R3 to generate the third shifted voltage V_{H2}. The third terminal of fifth transistor M5 is coupled to the third terminal of the sixth transistor M6. The third terminal of fifth transistor M5 and the third terminal of the sixth transistor M6 are coupled to the power source.

The fourth gain shifting circuit 56 includes a seventh transistor M7 and an eighth transistor M8. The seventh transistor M7 includes a first terminal, a second terminal, and a third terminal. The first terminal of the seventh transistor M7 receives the second input voltage VIN−. The eighth transistor M8 includes a first terminal, a second terminal, and a third terminal. The first terminal of the eighth transistor M8 receives the second voltage level VCM2. The second terminal of the eighth transistor M8 is coupled to one terminal of a fourth resistor R4, and the other terminal of the fourth resistor R4 is coupled to the second terminal of the seventh transistor M7 to generate the fourth shifted voltage V_{L2}. The third terminal of the seventh transistor M7 is coupled to the third terminal of the eighth transistor M8. The third terminal of the seventh transistor M7 and the third terminal of the eighth transistor M8 are coupled to the power source. A value of the first resistor R1, a value of the second resistor R2, a value of the third resistor R3, and a value of the fourth resistor R4 are the same. The first voltage level VCM1 and the second voltage level VCM2 are the same.

The signal processing circuit 58 includes a first operational amplifier 582 and a second operational amplifier 584. The first operational amplifier includes a first input terminal (+) and a second input terminal (−).The first input terminal (+) of the first operational amplifier 582 receives the first shifted voltage V_{H1}. The second input terminal (−) of the first operational amplifier 582 receives the second shifted voltage V_{L1}. The second operational amplifier 584 includes a first input terminal (+) and a second input terminal (−). The first input terminal (+) of the second operational amplifier 584 receives the third shifted voltage V_{H2}. The second input terminal (−) of the second operational amplifier 584 receives the fourth shifted voltage V_{L2}. The first operational amplifier 582 generates a first positive output (for example, Vₒₗ₊) and a first negative output (for example, Vₒ₁₋) according to the first shifted voltage V_{H1} and the second shifted voltage V_{L1}. The second operational amplifier 584 generates a second positive output (for example, Vₒ₂₊) and a second negative output (for example, Vₒ₂₋) according to the third shifted voltage V_{H2} and the fourth shifted voltage V_{L2}. Thereafter, an energy of a signal of the first positive output and an energy of a signal of the second positive output are combined, and an energy of a signal of the first negative output and an energy of a signal of the second negative output are combined, so as to generate a differential output signal VOUT. In this embodiment, the differential output signal VOUT includes a first differential output terminal (+) and a second differential output terminal (−). In this embodiment, the first differential output terminal (+) of the differential output signal VOUT is a positive terminal with a voltage value of (Vₒ₁₊+Vₒ₂₊). The second differential output terminal of the differential output signal VOUT is a negative terminal with a voltage value of (Vₒ₁₋+Vₒ₂₋).

In this embodiment of FIG. 7, similar to conditions in description related to FIG. 2, it is assumed that G1 is a gain of the first gain shifting circuit 50, G2 is a gain of the second gain shifting circuit 52, G3 is a gain of the third gain shifting circuit 54, and G4 is a gain of the fourth gain shifting circuit 56. In this embodiment, a value of voltage generated by IB*R1 may be the ΔV described in FIG. 6. Since the value of the first resistor R1, the value of the second resistor R2, the value of the third resistor R3, and the value of the fourth resistor R4 are the same, a value of voltage generated by IB*R2, a value of voltage generated by IB*R3, and a value of voltage generated by IB*R4 may also be the ΔV described in FIG. 6. Therefore, a voltage drop generated by the first resistor R1, a voltage drop generated by the second resistor R2, a voltage drop generated by the third resistor R3, and a voltage drop generated by the fourth resistor R4 are the same. In the following description, IB*R1 is used as an example. In this embodiment, the first voltage level VCM1 and the second voltage level VCM2 are the same, and VCM1 is used as an example in the following description. In a first condition, a value of VIN+ (or VIN−) is greater than a value of VCM1, and a difference between the value of VIN+ (or VIN−) and the value of VCM1 is much greater than a value of IB*R1. In a third condition, the value of VIN+ (or VIN−) is less than the value of VCM1, and a difference between the value of VIN+ (or VIN−) and the value of VCM1 is much greater than the value of IB*R1. In the first condition or in the third condition, G1=G2 and G3=G4. Therefore, G1−G2=0 and G3−G4=0. Consequently, VOUT=0. It is noted that the above description is described by mathematical operations for easy to understand. However, the signal processing circuit 58 is not limited to a mathematical operation circuit or a digital circuit. In one embodiment, the signal processing circuit 58 is an analog circuit and the operation of addition may be implemented by an energy combination of signals. In addition, since there may be an error (or inaccuracy) in a circuit, the equal sign “=” does not necessarily mean equal, the equal sign “=” may mean exactly equal or substantially equal. For example, in the equation of G1−G2=0, G1−G2 is not necessarily equal to 0. The equation of G1−G2=0 may mean that G1−G2 is substantially equal to 0.

Other circuits shown in FIGS. 6 and 7, for example, a transistor M9, a transistor M10, a transistor M11, and a transistor M12, similar to the transistor M5 and the transistor M6 in FIGS. 2 and 3, provide constant currents IBs as current sources. However, the disclosure is not limited thereto.

It is noted that although BJTs are considered as examples of the transistors M1-M8 in FIGS. 6 and 7, the disclosure is not limited thereto. In one embodiment, the transistors M1-M8 may be MOSFETs. In another embodiment, the transistors M1-M8 may be any combination of BJTs and MOSFETs. Taken a BJT shown in FIGS. 6 and 7 as an example, a first terminal of the BJT is a base terminal, a second terminal of the BJT is an emitter terminal, and a third terminal of the BJT is a collector terminal. If a MOSFET is used for any transistor of transistors M1-M8 in FIGS. 7 and 8, for example, a first terminal of the MOSFET is a gate terminal, a second terminal of the MOSFET is a source terminal, and a third terminal of the MOSFET is a drain terminal. However, the disclosure is not limited thereto. In addition, the transistors in embodiments of the disclosure may be N-type transistors or P-type transistors.

It is noted that the contents of FIGS. 5-7 that are the same or similar to contents of FIGS. 1A-4 are not described again. In addition to the function and ways mentioned in description of FIGS. 1-4A, the contents of FIGS. 5-7 uses the differential circuit to enhance the function of voltage clamping and to achieve better linearity of a passing band of input voltages.

From the above description, it can be known that the voltage clamping circuit uses a plurality of gain shifting circuits and a signal processing circuit to generate an output voltage. Therefore, high-speed voltage clamping may be achieved by a circuit without a diode component, and the adjustment of the central voltage level is simple.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A voltage clamping circuit, comprising:
a first gain shifting circuit configured to receive a first input voltage and a first voltage level to perform a first gain shifting to generate a first shifted voltage;
a second gain shifting circuit configured to receive the first input voltage and a second voltage level to perform a second gain shifting to generate a second shifted voltage; and
a signal processing circuit configured to receive the first shifted voltage and the second shifted voltage to generate a difference value of the first shifted voltage and the second shifted voltage, and generate an output voltage according to the difference value, such that the voltage clamping circuit achieves an implementation of a passing band or a rejection band of the first input voltage.

2. The voltage clamping circuit of claim 1, wherein the signal processing circuit comprises an operational amplifier having a first input terminal and a second input terminal configured to receive the first shifted voltage and the second shifted voltage, respectively, to generate the output voltage.

3. The voltage clamping circuit of claim 2, wherein:
the first gain shifting circuit comprises:
a first transistor having a first terminal and a second terminal, wherein the first terminal of the first transistor is configured to receive the first input voltage; and
a second transistor having a first terminal and a second terminal, wherein the first terminal of the second transistor is configured to receive the first voltage level, and the second terminal of the second transistor is coupled to the second terminal of the first transistor to generate the first shifted voltage; and
the second gain shifting circuit comprises:
a third transistor having a first terminal and a second terminal, wherein the first terminal of the third transistor is configured to receive the first input voltage; and
a fourth transistor having a first terminal and a second terminal, wherein the first terminal of the fourth transistor is configured to receive the second voltage level, and the second terminal of the fourth transistor is coupled to the second terminal of the third transistor to generate the second shifted voltage, and
wherein the first voltage level is different from the second voltage level.

4. The voltage clamping circuit of claim 3, wherein at least one of the first transistor, the second transistor, the third transistor, and the fourth transistor is a bipolar junction transistor (BJT) or a metal-oxide-semiconductor field-effect transistor (MOSFET), and wherein a first terminal of the BJT is a base terminal, a second terminal of the BJT is an emitter terminal, a first terminal of the MOSFET is a gate terminal, and a second terminal of the MOSFET is a source terminal.

5. The voltage clamping circuit of claim 2, further comprising a first resistor and a second resistor, wherein:
the first gain shifting circuit comprises:
a first transistor having a first terminal configured to receive the first input voltage and a second terminal coupled to one terminal of the first resistor; and
a second transistor having a first terminal configured to receive the first voltage level and a second terminal coupled to the other terminal of the first resistor to generate the first shifted voltage; and
the second gain shifting circuit comprises:
a third transistor having a first terminal and a second terminal, wherein the first terminal of the third transistor is configured to receive the first input voltage; and
a fourth transistor having a first terminal configured to receive the second voltage level and a second terminal coupled to one terminal of the second resistor with the other terminal of the second resistor coupled to the second terminal of the third transistor to generate the second shifted voltage,
wherein the first voltage level and the second voltage level are the same.

6. The voltage clamping circuit of claim 5, wherein a value of the first resistor and a value of the second resistor are the same.

7. The voltage clamping circuit of claim 5, wherein a voltage drop generated by the first resistor and a voltage drop generated by the second resistor are the same.

8. The voltage clamping circuit of claim 5, wherein at least one of the first transistor, the second transistor, the third transistor, and the fourth transistor is a bipolar junction transistor (BJT) or a metal-oxide-semiconductor field-effect transistor (MOSFET), and wherein a first terminal of the BJT is a base terminal, a second terminal of the BJT is an emitter terminal, a first terminal of the MOSFET is a gate terminal, and a second terminal of the MOSFET is a source terminal.

9. The voltage clamping circuit of claim 1, further comprising:
a third gain shifting circuit configured to receive a second input voltage and the first voltage level to perform a third gain shifting to generate a third shifted voltage; and
a fourth gain shifting circuit configured to receive the second input voltage and the second voltage level to perform a fourth gain shifting to generate a fourth shifted voltage,
wherein the signal processing circuit is further configured to receive the third shifted voltage and the fourth shifted voltage to generate the output voltage, such that the voltage clamping circuit achieves an implementation of a passing band or a rejection band of the first input voltage and the second input voltage.

10. The voltage clamping circuit of claim 9, wherein the signal processing circuit comprises:
a first operational amplifier having a first input terminal and a second input terminal configured to receive the first shifted voltage and the second shifted voltage, respectively, to generate a first positive output and a first negative output; and
a second operational amplifier having a first input terminal and a second input terminal configured to receive the third shifted voltage and the fourth shifted voltage, respectively, to generate a second positive output and a second negative output,
wherein the signal processing circuit combines an energy of a signal of the first positive output and an energy of a signal of the second positive output, and combines an energy of a signal of the first negative output and an energy of a signal of the second negative output to generate the output voltage.

11. The voltage clamping circuit of claim 10, wherein:
the first gain shifting circuit comprises:
a first transistor having a first terminal and a second terminal, wherein the first terminal of the first transistor is configured to receive the first input voltage; and
a second transistor having a first terminal configured to receive the first voltage level and a second terminal coupled to the second terminal of the first transistor to generate the first shifted voltage;
the second gain shifting circuit comprises:
a third transistor having a first terminal and a second terminal, wherein the first terminal of the third transistor is configured to receive the first input voltage; and
a fourth transistor having a first terminal configured to receive the second voltage level and a second terminal coupled to the second terminal of the third transistor to generate the second shifted voltage;
the third gain shifting circuit comprises:
a fifth transistor having a first terminal and a second terminal, wherein the first terminal of the fifth transistor is configured to receive the second input voltage; and
a sixth transistor having a first terminal configured to receive the first voltage level and a second terminal coupled to the second terminal of the fifth transistor to generate the third shifted voltage; and
the fourth gain shifting circuit comprises:
a seventh transistor having a first terminal and a second terminal, wherein the first terminal of the seventh transistor is configured to receive the second input voltage; and
an eighth transistor having a first terminal configured to receive the second voltage level and a second terminal coupled to the second terminal of the seventh transistor to generate the fourth shifted voltage,
wherein the first voltage level is different from the second voltage level.

12. The voltage clamping circuit of claim 11, wherein at least one of the first transistor, the second transistor, the third transistor, the fourth transistor, the fifth transistor, the sixth transistor, the seventh transistor, and the eighth transistor is a bipolar junction transistor (BJT) or a metal-oxide-semiconductor field-effect transistor (MOSFET), and wherein a first terminal of the BJT is a base terminal, a second terminal of the BJT is an emitter terminal, a first terminal of the MOSFET is a gate terminal, and a second terminal of the MOSFET is a source terminal.

13. The voltage clamping circuit of claim 10, wherein:
the first gain shifting circuit comprises:
a first transistor having a first terminal configured to receive the first input voltage and a second terminal coupled to one terminal of a first resistor; and
a second transistor having a first terminal configured to receive the first voltage level and a second terminal coupled to the other terminal of the first resistor to generate the first shifted voltage;
the second gain shifting circuit comprises:
a third transistor having a first terminal and a second terminal, wherein the first terminal of the third transistor is configured to receive the first input voltage; and
a fourth transistor having a first terminal configured to receive the second voltage level and a second terminal coupled to one terminal of a second resistor with the other terminal of the second resistor coupled to the second terminal of the third transistor to generate the second shifted voltage;
the third gain shifting circuit comprises:
a fifth transistor having a first terminal configured to receive the second input voltage and a second terminal coupled to one terminal of a third resistor; and
a sixth transistor having a first terminal configured to receive the first voltage level and a second terminal coupled to the other terminal of the third resistor to generate the third shifted voltage;
the fourth gain shifting circuit comprises:
a seventh transistor having a first terminal and a second terminal, wherein the first terminal of the seventh transistor is configured to receive the second input voltage; and
an eighth transistor having a first terminal configured to receive the second voltage level and a second terminal coupled to one terminal of a fourth resistor with the other terminal of the fourth resistor coupled to the second terminal of the seventh transistor to generate the fourth shifted voltage,
wherein the first voltage level and the second voltage level are the same.

14. The voltage clamping circuit of claim 13, wherein a value of the first resistor, a value of the second resistor, a value of the third resistor, and a value of the fourth resistor are the same.

15. The voltage clamping circuit of claim 13, wherein a voltage drop generated by the first resistor, a voltage drop generated by the second resistor, a voltage drop generated by the third resistor, and a voltage drop generated by the fourth resistor are the same.

16. The voltage clamping circuit of claim 13, wherein at least one of the first transistor, the second transistor, the third transistor, the fourth transistor, the fifth transistor, the sixth transistor, the seventh transistor, and the eighth transistor is a bipolar junction transistor (BJT) or a metal-oxide-semiconductor field-effect transistor (MOSFET), and wherein a first terminal of the BJT is a base terminal, a second terminal of the BJT is an emitter terminal, a first terminal of the MOSFET is a gate terminal, and a second terminal of the MOSFET is a source terminal.

17. The voltage clamping circuit of claim 1, which operates at about 1 GHz to about 3 GHz or at about 3 GHz to about 5 GHz.

18. The voltage clamping circuit of claim 1, which is implemented in an integrated circuit or a system circuit.
